(19) United States
(12) Patent Application Publication
(10) Pub. No.: US 2025/0058797 A1
(43) Pub. Date: Feb. 20, 2025

(54) COMPUTER-IMPLEMENTED METHOD AND SYSTEM FOR VALIDATING A BEHAVIOR PLANNER FOR AN AT LEAST PARTIALLY AUTOMATED VEHICLE

(71) Applicant: Robert Bosch GmbH, Stuttgart (DE)

(72) Inventors: Michael Rittel, Markgroeningen (DE); Christian Heinzemann, Vellmar (DE); Daria Stepanova, Leonberg (DE); Jens Oehlerking, Stuttgart (DE); Martin Butz, Steinheim An Der Murr (DE); Martin Herrmann, KORNTAL (DE)

(21) Appl. No.: 18/783,692

(22) Filed: Jul. 25, 2024

(30) Foreign Application Priority Data
Aug. 14, 2023 (DE) 10 2023 207 806.6

(51) Int. Cl. B60W 60/00; B60W 50/06

(52) U.S. Cl. CPC B60W 60/001; B60W 50/06

(57) ABSTRACT

A computer-implemented method for validating a behavior planner for an automated vehicle. The behavior planner has a database having previously defined partial situations and an evaluation model for each partial situation to break down a given situation into partial situations of the database and, based on the associated evaluation models, to determine boundary conditions for permissible behavior options of the vehicle in the given situation, as a combination of boundary conditions of the individual partial situations. The evaluation models of the partial situations are made available in a declarative program representation which enables the determination of formally explorable boundary conditions for permissible behavior options of the vehicle in the particular partial situation. A test situation is predefined as a composition of selected partial situations. The declarative program representations of the evaluation models of the selected partial situations are combined to form a combined program representation of the evaluation models.

### CROSS REFERENCE

The present application claims the benefit under 35 U.S.C. § 119 of German Patent Application No. DE 10 2023 207 806.6 filed on Aug. 14, 2023, which is expressly incorporated herein by reference in its entirety.

### BACKGROUND INFORMATION

The present invention relates to a computer-implemented method and a system for validating a behavior planner for an at least partially automated vehicle, which is also referred to below as an ego vehicle. The behavior planner in question here has a database having previously defined partial situations and at least one evaluation model for each partial situation in order to break down a given situation into partial situations in the database and, on the basis of the associated evaluation models, to determine boundary conditions for permissible behavior options of the vehicle in the given situation, namely as a combination of boundary conditions of the individual partial situations.

Such a behavior planner is described in German Patent Application No. DE 10 2022 214 276.

In the paper M. Butz et al., “SOCA: Domain Analysis for Highly Automated Driving Systems,” 2020 IEEE 23rd International Conference on Intelligent Transportation Systems (ITSC), 2020, pp. 1-6, doi: 10.1109/ITSC45102.2020.9294438, the so-called SOCA method is presented. With the aid of the SOCA method, traffic situations are analyzed, with the aim of determining boundary conditions for or requirements for the behavior of an automated ego vehicle in the particular traffic situation. For this purpose, firstly an abstract description of the traffic situation to be analyzed is generated. This description uses so-called zone graphs. A zone graph abstracts the traffic situation to be analyzed by representing the real road situation by a corresponding abstract traffic infrastructure element (static road geometry) having different zones that are relevant for the driving intention of the ego vehicle but are initially specified neither with regard to their size nor with regard to their position. The different zones can represent different map regions, possible traffic flows, objects, etc. On the basis of this abstract description of the traffic situation, the possible developments or the behavior of the road users involved are then determined and morphologically analyzed in order to determine boundary conditions for the behavior of the ego vehicle in the analyzed traffic situation. It is noteworthy that the results or boundary conditions obtained in this way initially apply to all traffic situations with the same zone graph. A specification is not performed until the results are data-loaded with the situation-specific parameters of the analyzed traffic situation.

The SOCA approach enables the analysis and formalization of individual traffic situations. To be sure, these individual situations can be partially generalized through parameterization. However, the requirements for the behavior of an ego vehicle in a complex operational design domain (ODD) cannot be formalized with this approach. This is mainly due to the fact that the behavior of the ego vehicle is subject to restrictions and requirements imposed by various elements of the ODD and that these can occur repeatedly and in different contexts. The SOCA approach with a focus on individual traffic situations is not sufficiently scalable for this purpose.

A substantial aspect for the performance of the behavior planner in question is the database having the previously defined partial situations and the associated evaluation models. The definition of partial situations plays a special role here. Thus, if possible, all operating conditions and deployment situations of the ego vehicle provided for in the ODD should be able to be broken down into partial situations in the database, i.e. the database must comprise a corresponding variety of partial situations. Furthermore, the individual partial situations should be “tailored” in such a way that the associated evaluation model takes into account as many influencing factors as possible on the behavior of the ego vehicle and specifies corresponding boundary conditions for the permissible behavior of the ego vehicle in this partial situation.

### SUMMARY

The present invention provides measures for systematically testing a behavior planner of the type in question here. These measures enable not only a validation of the behavior planner for a predefined ODD, but also an evaluation of the database of the behavior planner. In particular, this makes it possible to check to what extent the previously defined partial situations and associated evaluation models address certain borderline situations of the ODD.

This is achieved according to an example embodiment of the present invention by making the evaluation models of the partial situations available in a declarative program representation, which enables the determination of formally explorable boundary conditions for permissible behavior options of the vehicle in the particular partial situation. The validation is performed on the basis of test situations that are predefined as a composition of selected partial situations. The result of the behavior planner for a test situation predefined in this way is determined by initially combining the declarative program representations of the evaluation models of the selected partial situations into a combined program representation of the evaluation models. The formally explorable boundary conditions for permissible behavior options of the vehicle in the predefined test situation are then determined on the basis of the combined program representation of the evaluation models.

According to an example embodiment of the present invention, it has been recognized that methods from the field of declarative problem-solving, which have been developed in the context of knowledge representation, logic programming, satisfiability solving and database theory, can also be advantageously used in the validation of behavior planners of the type in question here. With methods for declarative problem-solving, complex tasks are described in the form of a declarative program representation, which enables the deployment of highly efficient software tools to find solutions, so-called solver tools, for the described tasks. In addition, declarative program representations of subtasks can be easily combined so that the resulting combined program representation can then be used as a basis for solving the overall task.

For the deployment according to the present invention of these methods, it proves to be advantageous that the evaluation models of the partial situation are usually already available in declarative form, which can either be used directly as a declarative program representation or can be very easily converted into a declarative program representation.

The present invention also takes advantage of the fact that the solutions generated in this way are formally explorable. This allows the solutions—in this case, the boundary conditions for permissible vehicle behavior—to be analyzed automatically, which is essential for comprehensive validation of the behavior planner.

According to an example embodiment of the present invention, the concept of partial situations is used in order to construct test situations for the purpose of validation. Thus, “interesting” situations for the autonomous vehicle can be investigated and also found incrementally with the help of tools. What is considered “interesting” situations depends on the goal of the analysis. As a rule, these will be scenarios that are particularly challenging for the system. These include, for example, situations in which, according to the behavior planner, the autonomous vehicle does not have any behavior options available that meet all of the situation-specific boundary conditions required by the evaluation models. Such situations are called dilemma situations.

Thus, the validation method according to the present invention enables a systematic formalization and exploration of a given ODD, for example as a release argument for a behavior planner of the type in question here. Furthermore, it can be used for the automated recognition of critical situations in a given behavioral framework of the ego vehicle and for the derivation of corresponding test situations. The validation method according to the present invention can also be used advantageously within the framework of the development process, namely in the definition of the partial situations of the database of a behavior planner. In query cycles with an incremental configuration of the partial situations, the set of partial situations and associated evaluation models can be systematically extended and improved in order to configure the behavior planner for a predefined ODD.

In principle, there are different possibilities for the definition of partial situations and the implementation and representation of corresponding evaluation models for a behavior planner of the type in question here.

In a preferred example embodiment of the present invention, each partial situation is defined as a situation class that is at least partially determined by an ego vehicle with behavior model, at least one traffic infrastructure element and a general situation context. Optionally, the definition of a partial situation can also comprise at least one other road user with a behavior model. Each partial situation and the associated evaluation model can be parameterized in a situation-specific manner and/or instantiated by providing situation-specific information. In this embodiment of the present invention, predefining a test situation comprises not only the selection of suitable partial situations of the database, but also a defined parameterization and/or instantiation of the selected partial situations or evaluation models.

The partial situations defined in this way can be combined very flexibly in order to create complex situations. For example, a plurality of instances of the same partial situation with different parameterization and/or data can be used to create a complex situation. Here, an example of such a complex situation is a pedestrian crossing in which a plurality of pedestrians move at individual speeds and orientations while the ego vehicle approaches the pedestrian crossing. This complex situation can be easily constructed from a plurality of instances of a partial situation, wherein each instance in each case comprises the ego vehicle and the pedestrian crossing as a traffic infrastructure element along with exactly one of the pedestrians.

As mentioned above, the database of the previously defined partial situations should be compiled in such a way that many different traffic situations, and in particular the most common traffic situations of the ODD of the ego vehicle, can be completely broken down into partial situations of the database. The partial situations should on the one hand be so generic that they occur in as many different traffic situations as possible, but on the other hand also be so specific that the associated evaluation model has a certain informative value.

A very effective method for analyzing traffic situations with the aim of determining boundary conditions for the behavior of an automated ego vehicle in the relevant traffic situation is the SOCA method described above. The SOCA method is also suitable for defining partial situations and for generating evaluation models for partial situations, as used by a behavior planner of the type in question here. In this case, the evaluation models are based on a break down of the relevant partial situation into zone graphs and on a morphological behavior analysis of the road users involved. The evaluation models are generated here in the form of Zwicky boxes. A Zwicky box is a fully formalized description of the boundary conditions or limitations for the permissible behavior of the ego vehicle in the particular partial situation, namely for all meaningful instantiations of this partial situation. The totality of permissible behaviors defined in this way for a partial situation is also referred to as the “partial behavior constraint space.”

The Zwicky boxes generated with the aid of the SOCA method—like the corresponding partial situations—can be combined very easily and flexibly in order to determine boundary conditions for the permissible behavior of the ego vehicle in complex situations constructed in this way.

The combination of evaluation models of a plurality of partial situations of a test situation must take into account the fact that some partial situations or instances of partial situations can interact and can even exclude one another. If the evaluation models of the partial situations of the behavior planner to be validated are not already present in the declarative program representation required by the present invention, they are transformed into such a declarative program representation in one embodiment of the validation method according to the present invention, namely in such a way that the semantics of the combination of the evaluation models are retained. That is, any combination of transformed evaluation models provides the same boundary conditions for the permissible behavior of the ego vehicle as the corresponding combination of evaluation models in the database of the behavior planner.

Answer set programs are particularly well suited as declarative program representations for the validation method described here, as described, for example, in the paper G. Brewka, T. Eiter, M. Truszczynski, “Answer Set Programming at a Glance” in CACM, December 2011, vol. 54, no. 12, pp 93-103. Answer set programming (ASP) is a declarative problem-solving paradigm for which a number of highly efficient ASP solvers have already been developed and are therefore available. This makes it possible to model complex tasks, such as behavior planning, and also to find solutions for these tasks.

As mentioned above, the test situations are usually selected so that they lie within a predefined operational design domain (ODD). Advantageously, the test situations are predefined automatically, in particular with the aid of a test configuration database in which at least the following data is stored for each test situation:
Data for identifying the individual partial situations of the test situation,
Data for parameterizing the individual partial situations and/or
Data for instantiating the individual partial situations.

In a preferred development of the method according to the present invention, a results database is generated, in which the formally explorable boundary conditions for permissible behavior options of the vehicle determined for each predefined test situation are stored. Such a results database can then be searched automatically, for example with the aid of suitable analysis tools and previously defined search queries, in order to identify specific test situations and/or specific behavior options of the vehicle, such as fallback behavior options. In this way, it is possible to check whether the behavior planner, with the data basis available to him, is providing acceptable behavior options in all possible ODD situations. The evaluation of the behavioral options can, for example, be performed on a data-based basis or by comparison with simulation results, by expert assessment or by behavioral studies with test subjects. On the basis of such an evaluation, the database can then—if necessary—be supplemented by further partial situations, and/or the existing partial situations in the database can be modified.

In addition to the validation method described above, a computer-implemented system for validating a behavior planner of the type in question is also provided. According to the an example embodiment of the present invention, such a system comprises a transformation tool for generating declarative program representations for the evaluation models of the database of the behavior planner, wherein the transformation tool is designed in such a way that the semantics of the combination of the evaluation models are independent of the representation. Furthermore, the system according to the present invention comprises a composition tool for generating combined program representations as a combination of the declarative program representations of evaluation models, in particular of evaluation models of selected partial situations, the composition of which represents a predefined test situation. On the basis of the combined program representations, formally explorable boundary conditions for permissible behavior options of the vehicle in test situations can then be determined.

In a preferred example embodiment of the present invention, the transformation tool is designed to transform evaluation models, which are based on a break down of the particular partial situation into zone graphs and a morphological behavior analysis of the road users involved (SOCA method) and are available in the form of Zwicky boxes, into an answer set program representation.

The composition tool is preferably designed to select the corresponding partial situations of the database for each test situation and to parameterize and/or instantiate the selected partial situations in a test situation-specific manner. Advantageously, the composition tool has a configuration database available for this purpose, in which at least the following data is stored for each test situation:
Data for identifying the individual partial situations of the test situation,
Data for parameterizing the individual partial situations and/or
Data for instantiating the individual partial situations.

In a preferred development of the present invention, the system further comprises a results database for storing test results in the form of formally explorable boundary conditions for permissible behavior options of the vehicle that have been determined for a predefined test situation, wherein the results database can be automatically searched with the aid of previously defined search queries, in order to identify specific test situations and/or specific behavior options of the vehicle.

### BRIEF DESCRIPTION OF THE DRAWINGS

Exemplary embodiments and advantageous further developments of the present invention are explained in more detail below in conjunction with the figures.

FIG. 1 illustrates the concept of a partial situation used to plan the behavior of an ego vehicle and its role within the framework of the validation method according to an example embodiment of the present invention.

FIG. 2 illustrates the validation method according to the present invention and a corresponding system using an exemplary embodiment of the present invention.

FIG. 3 illustrates the validation concept according to an example embodiment of the present invention using a block diagram.

### DETAILED DESCRIPTION OF EXAMPLE EMBODIMENTS

A substantial aspect for the behavior planner in question here is an adequate definition of partial situations that can be formalized independently of one another and analyzed with the aid of associated evaluation models. Each evaluation model defines the boundary conditions for the permissible behavior options of the ego vehicle in the particular partial situation, i.e. a “partial behavior constraint space.” The adequately defined partial situations together with the associated evaluation models form the database of the behavior planner. This is also a prerequisite or subject of the validation according to the present invention. With such a database, a variety of more or less complex traffic situations can be assembled or constructed.

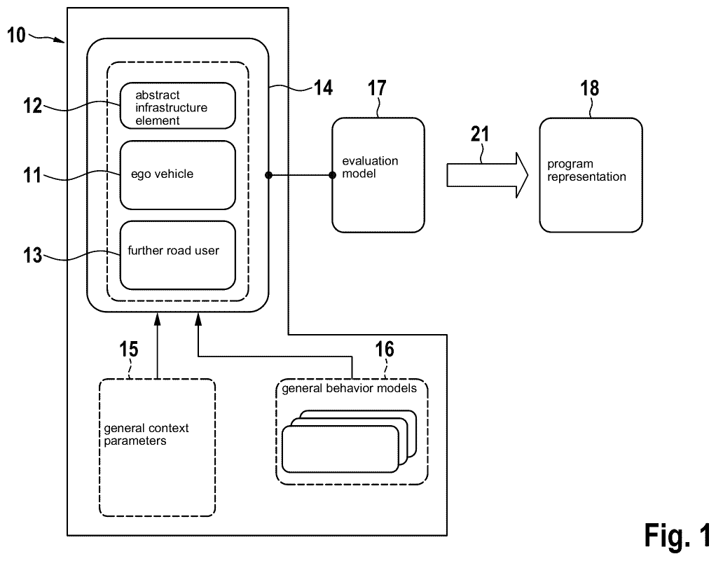

FIG. 1 illustrates the concept of a partial situation and its use within the scope of the present invention. The present partial situation is a situation class which is described abstractly by certain properties or elements. The description of the partial situation 10 shown here substantially comprises three elements: the ego vehicle 11, an abstract traffic infrastructure element 12, and a further road user 13. Each of these three elements 11, 12 and 13 is characterized by models, rules, state parameters, and/or state variables. In this case, in the exemplary embodiment shown, the ego vehicle 11 is characterized by its driving intention, dynamic state variables, such as speed, acceleration and orientation, system parameters, such as technical vehicle parameters, and a behavior model, such as defensive driving or sporty driving. The abstract traffic infrastructure element 12 could be, for example, an intersection, a road junction or a road section. It is characterized here by a zone graph according to the SOCA method and by the traffic regulations applicable to this traffic infrastructure element, i.e., for example, “right before left.” The further road user 13 is likewise characterized here by his “movement” intention and by dynamic state variables as well as by a behavior model with which assumptions can be made for the behavior of the further road user. The elements 11, 12 and 13 are embedded in a general situation context 14, into which not only general context parameters 15 but also general behavior models 16 of road users flow. Road state parameters, weather parameters and lighting parameters are mentioned here as examples of general context parameters 15. The general behavior models 16 could comprise motion models for classes of road users, such as pedestrians, cyclists, motorcyclists, car drivers, etc., and possibly model interactions between road users. The behavior models 16 can be modeled, for example, by continuous motion models in the form of differential equations, by Markov decision processes or by discrete behavior spaces (discrete decision spaces).

The partial situation 10 is defined by all these elements 11 to 16. Each of these elements 11 to 16 can restrict the permissible behavior of the ego vehicle. In order to be taken into account in behavior planning, all these sources of influence must be explicitly described and/or mapped to formal parameters or decision alternatives in the “partial constraint behavior space.”

A partial situation 10 defined in this way along with the associated evaluation model 17 can be parameterized and instantiated by means of data input. In behavior planning, the partial situations identified in a given situation are data-loaded with situation-specific information and thus configured according to the given situation. Within the scope of the validation method according to the present invention, test situations are assembled or constructed by combining and appropriately specifying selected partial situations or associated evaluation models.

In the case of the exemplary embodiment described here, the partial situation 10 was analyzed with the aid of the SOCA method. An evaluation model 17 was thus generated, which can be used as a basis for the analysis of all instances of the partial situation 10. The evaluation model 17 is in the form of a Zwicky box or a set of Zwicky boxes. The correspondingly data-loaded evaluation model 17 then provides boundary conditions for permissible behavior options of the ego vehicle in the particular instance of the partial situation 10.

According to the present invention, the evaluation models of the partial situations are to be made available in a declarative program representation, which enables a determination of formally explorable boundary conditions for permissible behavior options of the vehicle in the particular partial situation.

The Zwicky boxes are a declarative form of representation. However, this cannot be automatically data-loaded and the boundary conditions for permissible behavioral options of the ego vehicle in the particular instance of partial situation 10, which are determined with the aid of Zwicky boxes, are initially not available in a formally explorable form. Therefore, the Zwicky box 17 of the partial situation 10 is transformed into a suitable declarative program representation 18, with which boundary conditions for permissible behavior options of the vehicle can be determined in a formally explorable form. It is a substantial aspect that the semantics of the combinations of the evaluation models are preserved during the transformation of the evaluation models, i.e. that the semantics of the combined evaluation models are independent of representation. In the exemplary embodiment described here, the Zwicky box 17 is transformed into an answer set program representation 18. A transformation tool 21 is provided for this purpose.

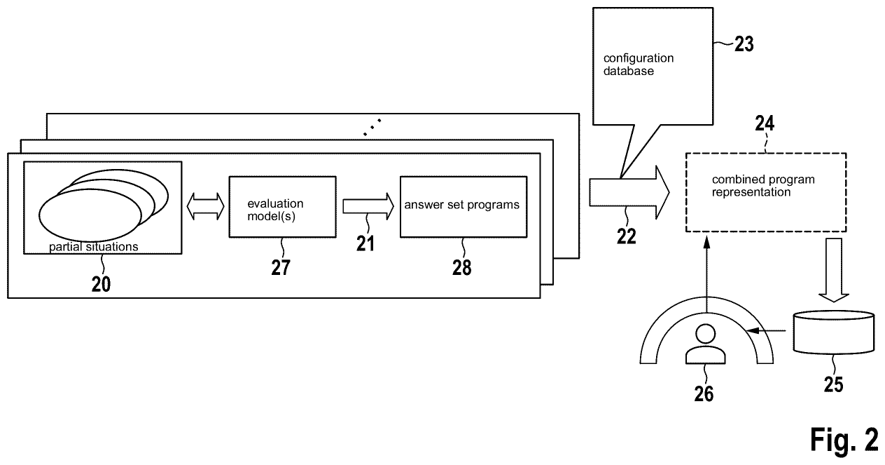

FIG. 2 illustrates the concept of the validation according to the present invention of a behavior planner of the type in question here. The behavior planner comprises a database with a plurality of different partial situations 20, which are defined here as explained in connection with FIG. 1. Each of these partial situations 20 represents a set of influence sources (partial behavior constraint source) that restrict the permissible behavior of the ego vehicle in the particular partial situation. The database of the behavior planner also comprises at least one evaluation model 27 for each partial situation 20. These evaluation models 27 define the boundary conditions for the permissible behavior options of the ego vehicle in the particular partial situation 20, i.e. a “partial behavior constraint space” in each case. As in the case of FIG. 1, the evaluation models 27 are initially available in the form of Zwicky boxes. With the aid of a transformation tool 21, the Zwicky boxes 27 are transformed into answer set programs 28, which provide a formally explorable representation of the boundary conditions for the permissible behavior options of the ego vehicle in the particular partial situation 20.

The validation method according to the present invention provides for constructing test situations, namely as a composition of selected partial situations of the database. These test situations are analyzed on the basis of the evaluation models of the selected partial situations, namely according to the present invention on the basis of the transformed declarative program representations of these evaluation models. With the aid of a composition tool 22, a combined program representation 24 is generated for each test situation, as a combination of the declarative program representations of the evaluation models of the selected partial situations. The composition tool 22 has access to a configuration database 23, in which data for identifying the individual partial situations of a test situation and test situation-specific data for parameterizing and instantiating the particular partial situations are stored. A combined program representation 24 thus data-loaded then provides formally explorable boundary conditions for permissible behavior options of the ego vehicle in the particular test situation as a result.

In the exemplary embodiment shown here, the results of the query/exploration are compiled in a results database 25 and made available to a user 26. Since the results are formally explorable, the results database 25 can be automatically searched for specific test situations using appropriately formulated search queries. In the case of an ASP representation of the results, a number of conventional tools are available, for example “clingo,” which is described in more detail at potassco.org.

It is a substantial aspect that a wide variety of more or less complex test situations can be assembled from the partial situations of the database. The boundary conditions for the permissible behavior options of the ego vehicle in such a test situation can be determined by logically linking the boundary conditions of all partial situations of the test situation. Redundant information for the ego vehicle is eliminated and the remaining boundary conditions can simply be linked together. This applies to the Zwicky box representation of the evaluation models 27 and also applies to the transformed evaluation models 28 in the ASP representation. The semantics of the combination of evaluation models are thus preserved during the transformation into the declarative program representation.

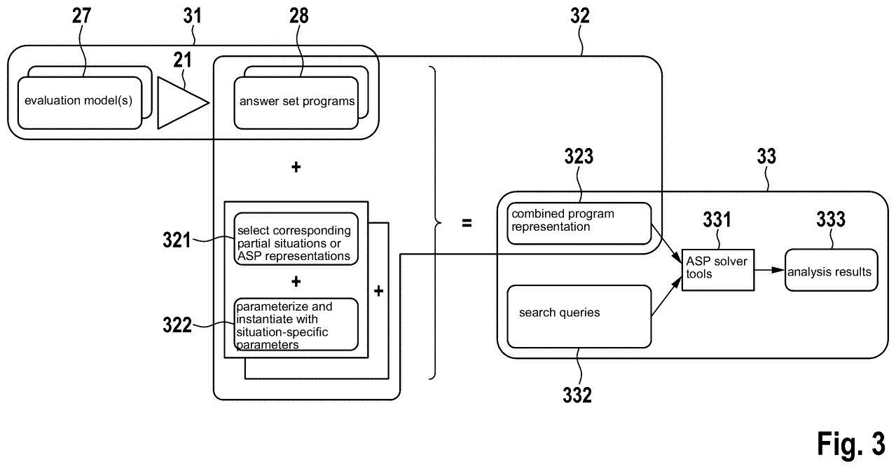

In the block diagram of FIG. 3, the validation concept according to the present invention is divided into three phases: a foundation phase 31, a configuration phase 32 and an exploration phase 33.

In the foundation phase 31, the evaluation models 27 of the database of the behavior planner to be validated are converted into a declarative program representation 28 with the aid of a transformation tool 21, in the present exemplary embodiment from Zwicky boxes 27 into an ASP representation 28.

In the configuration phase 32, results—i.e., boundary conditions for permissible behavior options of an ego vehicle—are determined for test situations that are constructed as a combination of selected partial situations of the database. For each test situation, the corresponding partial situations or the ASP representations of the associated evaluation models are initially selected—block 321. These are then parameterized and instantiated with test situation-specific parameters—block 322. The ASP representations thus data-loaded are finally combined to form a combined program representation 323 of the evaluation models.

In the exploration phase 33, the resulting combined ASP representation 323 is analyzed with the aid of ASP solver tools 331. Depending on the analysis objective, special search queries 332 can also be placed, for example to recognize dilemma situations. In any case, the ASP Solver Tools 331 provide analysis results 333 in the form of boundary conditions for permissible behavior options of an ego vehicle in the particular test situation.

Finally, it should be expressly mentioned once again that the validation method according to the present invention can be used both for an approval argument and within the framework of the development of a behavior planner of the type in question here, namely in the generation of the database of the behavior planner and in particular in the definition of the partial situations. The analysis of the results of the validation method allows conclusions to be drawn about the quality of the definition of the individual partial situations.

What is claimed is:

1. A computer-implemented method for validating a behavior planner for an at least partially automated vehicle, the behavior planner having a database having previously defined partial situations and at least one associated evaluation model for each partial situation in order to break down a given situation into the partial situations of the database and, based on the associated evaluation models, to determine boundary conditions for permissible behavior options of the vehicle in the given situation, as a combination of boundary conditions of individual partial situations associated with the given situation, the method comprising:
providing each of the evaluation models of the partial situations in a declarative program representation which enables the determination of formally explorable boundary conditions for permissible behavior options of the vehicle in each partial situation;
predefining at least one test situation is predefined as a composition of selected partial situations;
combining the declarative program representations of the evaluation models of the selected partial situations to form a combined program representation of the evaluation models of the selected partial situations; and
determining formally explorable boundary conditions for permissible behavior options of the vehicle in the test situation based on the combined program representation of the evaluation models of the selected partial situations.

2. The method according to claim 1, wherein each partial situation is defined as a situation class that is at least partially determined by at least one of the following elements:
(i) an ego vehicle having a behavior model,
(ii) at least one traffic infrastructure element,
(iii) a general situation context,
(iv) at least one other road user having a behavior model;
wherein each partial situation together with the associated evaluation model can be parameterized in a situation-specific manner and/or can be instantiated by data input having situation-specific information, and the predefining of the test situation includes a defined parameterization and/or instantiation of the selected partial situations or the evaluation models of the selected partial situations.

3. The method according to claim 1, wherein at least some of the evaluation models are based on breaking down the associated partial situation into zone graphs and a morphological behavior analysis of road users involved and are generated in as Zwicky boxes.

4. The method according to claim 1, wherein the evaluation models of the partial situations are each transformed into a declarative program representation which enables the determination of formally explorable boundary conditions for permissible behavior options of the vehicle in the particular partial situation, including into an answer set program representation, so that semantics of the combination of the evaluation models is independent of representation.

5. The method according to claim 1, wherein test situations are selected such that they lie within a predefined operational design domain.

6. The method according to claim 1, wherein test situations are predefined automatically using a configuration database in which at least the following data are stored for each test situation:
a. data for identifying the partial situations of the test situation, and/or
b. data for parameterizing the partial situations of the test situation, and/or
c. data for instantiating the partial situations of the test situation.

7. The method according to claim 1, wherein a results database is generated, in which the formally explorable boundary conditions for permissible behavior options of the vehicle determined for each predefined test situation are stored.

8. The method according to claim 7, wherein the results database is automatically searched using previously defined search queries in order to identify specific test situations and/or specific behavior options of the vehicle.

9. A computer-implemented system for validating a behavior planner for an at least partially automated vehicle, wherein the behavior planner has a database having previously defined partial situations and at least one associated evaluation model for each partial situation in order to break down a given situation into partial situations of the database and, based on the associated evaluation models, to determine boundary conditions for permissible behavior options of the vehicle in the given situation, as a combination of boundary conditions of the partial situations, the system comprising:
a transformation tool configured to generate declarative program representations for the evaluation models of the database of the behavior planner, wherein the transformation tool is configured in such a way that semantics of a combination of the evaluation models are independent of representation; and
a composition tool configured to generate combined program representations as a combination of the declarative program representations of evaluation models of selected partial situations, the composition of which represents a predefined test situation.

10. The system according to claim 9, wherein the transformation tool is configured to transform evaluation models, which are each based on a break down of the associated partial situation into zone graphs and a morphological behavior analysis of the road users involved and are in the form of Zwicky boxes, into an answer set program representation.

11. The system according to claim 9, wherein the composition tool is configured to construct test situations by selecting partial situations of the database, and parameterizing and/or instantiating the selected partial situations or the evaluation models associated with the selected partial situations.

12. The system according to claim 11, wherein the composition tool has a configuration database in which at least the following data are stored for each test situation:
a. data for identifying the partial situations of the test situation, and/or
b. data for parameterizing the partial situations of the test situation, and/or
c. data for instantiating the partial situations of the test situation.

13. The system according to claim 9, further comprising:
a results database configured to store test results in the form of formally explorable boundary conditions for permissible behavior options of the vehicle that have been determined for a predefined test situation, wherein the results database can be automatically searched using previously defined search queries in order to identify specific test situations and/or specific behavior options of the vehicle.
